(19) United States
(12) Patent Application Publication
(10) Pub. No.: US 2017/0027084 A1
(43) Pub. Date: Jan. 26, 2017

(54) CONTINUOUS FLUIDIC THERMAL INTERFACE MATERIAL DISPENSING

(71) Applicant: Delta Design, Inc., Poway, CA (US)

(72) Inventors: Samer KABBANI, San Marcos, CA (US); Jerry Ihor TUSTANIWSKYJ, Mission Viejo, CA (US); James Wittman BABCOCK, Escondido, CA (US); Thomas JONES, Escondido, CA (US)

(73) Assignee: Delta Design, Inc., Poway, CA (US)

(21) Appl. No.: 15/210,361

(22) Filed: Jul. 14, 2016

Related U.S. Application Data
(60) Provisional application No. 62/195,049, filed on Jul. 21, 2015.

(51) Int. Cl. H05K 7/20

(52) U.S. Cl. CPC H05K 7/20509

(57) ABSTRACT

A temperature control system for controlling a temperature of an electronic device during testing of the electronic device includes a thermal head having a device contact face configured to contact the electronic device during testing; a fluidic thermal interface material (TIM) dispenser configured to dispense a fluidic TIM to a location between a face of the electronic device and the device contact face of the thermal head; and a fluidic TIM dispenser controller configured to control the TIM dispenser such that the TIM dispenser dispenses the fluidic TIM during a test cycle of the electronic device.

### BACKGROUND OF THE INVENTION

The present application claims priority to U.S. Provisional Application No. 62/195,049, filed Jul. 21, 2015, which is hereby incorporated by reference in its entirety.

### BACKGROUND OF THE INVENTION

This section is intended to provide a background or context to the invention that is recited in the claims. The description herein may include concepts that could be pursued, but are not necessarily ones that have been previously conceived or pursued. Therefore, unless otherwise indicated herein, what is described in this section is not prior art to the description and claims in this application and is not admitted to be prior art by inclusion in this section.

The present disclosure relates generally to the field of thermal control and/or conditioning of an electronic device (also called a “device under test” or “DUT”), such as a semiconductor wafer or die undergoing electrical testing, or other devices that may be in use or undergoing testing. More particularly, the present disclosure relates to an apparatus and method for thermal control and/or conditioning of such device.

Various techniques have been developed to maintain the temperature of a semiconductor device at or near a predetermined set point temperature. For example, such systems and methods are described in U.S. Pat. No. 7,639,029, U.S. Pat. No. 6,489,793, U.S. Pat. No. 6,476,627, U.S. Pat. No. 6,389,225, U.S. Pat. No. 5,864,176, U.S. Pat. No. 5,844,208, U.S. Pat. No. 5,821,505, U.S. Pat. No. 5,420,521, U.S. Pat. No. 5,297,621, U.S. Pat. No. 5,104,661, U.S. Pat. No. 5,315,240, U.S. Pat. No. 5,205,132, U.S. Pat. No. 5,125,656, U.S. Pat. No. 5,309,090, U.S. Pat. No. 5,172,049, and U.S. Pat. No. 4,734,872, all of which are hereby incorporated by reference in their entireties.

Two specific examples of electronic devices that need to be tested near a constant temperature are packaged integrated chips, or bare chips which are unpackaged. Any type of circuitry can be integrated into the chips, such as digital logic circuitry, memory circuitry, or analog circuitry. The circuitry in the chips can be comprised of any type of transistors, such as field effect transistors or bipolar transistors.

One reason for trying to keep the temperature of a chip constant while it is tested is that the speed with which the chip operates may be temperature dependent. For example, a chip comprised of complementary field effect transistors (CMOS transistors) typically increases its speed of operation by about 0.3% per ° C. drop in chip temperature.

A common practice in the chip industry is to mass produce a particular type of chip, and then speed sort them and sell the faster operating chips at a higher price. CMOS memory chips and CMOS microprocessor chips are processed in this fashion. However, in order to determine the speed of such chips properly, the temperature of each chip must be kept nearly constant while the speed test is performed.

Maintaining the chip temperature near a constant set point is simple if the instantaneous power dissipation of the chip is constant or varies in a small range while the speed test is being performed. In that case, it is only necessary to couple the chip through a fixed thermal resistance to a thermal mass, which is at a fixed temperature. For example, if the maximum chip power variation is ten watts, and the coupling between the chip and the thermal mass is 0.2° C./watt, then the chip temperature will vary a maximum of 2° C.

However, if the instantaneous power dissipation of the chip varies up and down in a wide range while the speed test is being performed, then maintaining the chip temperature near a constant set point is very difficult. Each time the device power dissipation changes, its temperature and its speed will also change. Additionally, power dissipation increases with temperature, which can lead to thermal runaway and destruction of the chip.

The above problem is particularly severe in CMOS chips because their instantaneous power dissipation increases as the number of CMOS transistors that are switching ON or OFF increases. During the speed test of a CMOS chip, the number of transistors that are switching is always changing. Thus, the chip's power dissipation, temperature, and speed are always changing. Also, the magnitude of these changes increases as more transistors get integrated into a single chip, because the number of transistors that are switching at any particular instant will vary from none to all of the transistors on the chip.

One way to more quickly increase or lower the temperature of an electronic device during testing is by dispensing a fluid thermal interface material (TIM) onto the chip before contacting the electronic device with a thermal head for testing. For example, U.S. Pat. No. 5,864,176 discloses dispensing a liquid, such as water or a mixture of water and ethylene glycol, on the electronic device, and then pressing a surface of a heater against the electronic device, with the liquid therebetween. As a result, some of the liquid is squeezed from between the heater and the electronic device, and the remaining liquid fills microscopic gaps that exist between the electronic device and the heater. The TIM lowers thermal resistance between the chip and the thermal head, which makes it easier to raise and lower the temperature of the chip using the thermal head. In other words, the TIM causes the chip to be closer in temperature to a temperature controlled surface of the thermal head.

While the deposition of a thermal interface material on an electronic device before contacting the device with the heater is beneficial for many applications, during tests requiring long testing times and/or high testing temperatures, the thermal interface material can evaporate before testing is complete. The resultant increase in thermal resistance can cause the temperature of the electronic device to increase beyond the desired set point or beyond the desired maximum safe-to-test temperature. For example, the use of water as a thermal interface material may make it possible to test at 102° C. for 2 or 3 seconds or at 95° C. for 20 seconds, but as soon as the water evaporates, the temperature of the electronic device can quickly rise to 140 or 150° C., which may cause the device to fail the test, or may damage the device.

### SUMMARY OF THE INVENTION

One object of certain embodiments of the invention is to provide a temperature control system that reacts quickly to large variations in power dissipation within an electronic device and thereby maintain the device temperature at or near a constant set point temperature while the device is being tested.

According to one embodiment, a temperature control system for controlling a temperature of an electronic device during testing of the electronic device includes: a thermal head having a device contact face configured to contact the electronic device during testing; a fluidic thermal interface material (TIM) dispenser configured to dispense a fluidic TIM to a location between a face of the electronic device and the device contact face of the thermal head; and a fluidic TIM dispenser controller configured to control the TIM dispenser such that the TIM dispenser dispenses the fluidic TIM during a test cycle of the electronic device.

According to another embodiment, a method of controlling a temperature of an electronic device during testing of the electronic device includes: contacting a device contact face of a thermal head against an electronic device and testing the electronic device; and while contacting the device contact face of the thermal head against the electronic device and performing a test cycle, dispensing a fluidic thermal interface material to a location between a face of the electronic device and the device contact face of thermal head.

### BRIEF DESCRIPTION OF THE DRAWINGS

Embodiments of the invention are described by referring to the attached drawings, in which:

FIG. 1 is a schematic side view of a temperature control system in which a liquid thermal interface material (TIM) is dispensed through an interposed heater.

FIG. 2 is a schematic side view of a temperature control system in which the TIM is dispensed via a channel extending through a heat sink, a thermal interface, and an interposed heater that includes a pedestal.

FIG. 3 is a schematic side view of a temperature control system in which the TIM is dispensed via a pedestal of an interposed heater.

FIG. 4 is a schematic side view of a temperature control system in which the TIM is dispensed via a channel extending through a passive heat sink.

FIG. 5 is a schematic side view of a temperature control system in which the TIM is dispensed through a heat sink and a thermo-electric device.

FIG. 6 is a schematic side view of a temperature control system in which the TIM is dispensed through side injection.

FIG. 7 is a schematic side view of a temperature control system in which the interface gap between the thermal head and the electronic device is open to an ambient environment.

FIG. 8 is a schematic side view of a temperature control system in which the interface gap between the thermal head and the electronic device is sealed from an ambient environment.

FIG. 9 is a schematic bottom view of a device contact face of a thermal head in which a hydrophilic coating is disposed on a portion of the device contact face.

FIG. 10 is a schematic bottom view of a device contact face of a thermal head in which a hydrophobic coating is disposed on a portion of the device contact face.

FIG. 11 is a schematic bottom view of a device contact face of a thermal head in which a fluid sensor is disposed on a portion of a face of the device contact face.

FIG. 12 is a flow chart showing control of a TIM dispenser based on signals received from the fluid sensor shown in FIG. 11, or based on a thermal resistance between the electronic device and the thermal head.

FIG. 13 is a flow chart showing control of a TIM dispenser based on electronic device temperature, heater temperature, and electronic device power.

### DETAILED DESCRIPTION

In the following description, for purposes of explanation and not limitation, details and descriptions are set forth in order to provide a thorough understanding of embodiments of the present invention. However, it will be apparent to those skilled in the art that the present invention may be practiced in other embodiments that depart from these details and descriptions.

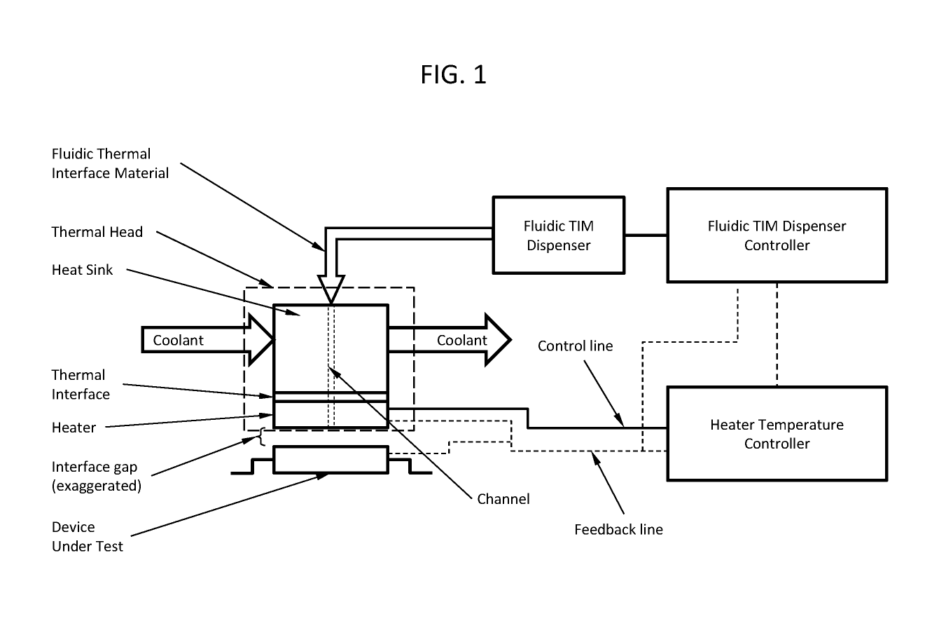

In some embodiments, depicted in FIGS. 1-12, a temperature control system is provided for maintaining a temperature of an electronic device at or near a set point temperature during testing of the electronic device. The system includes a thermal head having a device contact face configured to contact an electronic device during testing. The system further includes a fluidic TIM dispenser configured to dispense a fluidic TIM between a face of the electronic device and the face of the thermal head, and a fluidic TIM dispenser controller configured to control the TIM dispenser such that the TIM dispenser dispenses the fluidic TIM during testing of the electronic device.

### First Embodiment

In one embodiment, depicted in FIG. 1, the temperature control system includes a thermal head that includes a heater, a liquid cooled heat sink, and a thermal interface between the heater and the heat sink. The system further includes a fluidic TIM dispenser configured to dispense a TIM to a face of the thermal head that is configured to contact an electronic device, via a channel that extends through the heat sink, the thermal interface, and the heater. The system includes a fluidic TIM dispenser controller configured to control the fluidic TIM dispenser, and a heater temperature controller configured to control a temperature of the heater. The fluidic TIM dispenser controller and the heater temperature controller may be parts of the same controller unit, as indicated by the dashed line in FIG. 1.

### Thermal Head

In the embodiment shown in FIG. 1, the thermal head includes a heater having a face configured to contact the electronic device during testing. While the face of the heater contacts the electronic device, the electronic device is tested and its temperature is maintained at or near a set point.

In this embodiment, the heater is a thin, flat electric heater having a first face attached to the heat sink via the thermal interface, and a second, exposed face configured to contact the electronic device during testing. For example, the electric heater may be made of an aluminum nitride ceramic in which electrical resistors (not shown) are uniformly integrated for converting electrical power to heat.

The heat sink of FIG. 1 is a liquid-cooled heat sink having a hollow base in which cooling fins (not shown) are disposed. Liquid coolant enters the base from a first tube and exits the base through a second tube, as shown by the arrows labeled “coolant” in FIG. 1. The liquid coolant is circulated through the base by a pump (not shown) and held at a temperature that is lower than a predetermined setpoint temperature. The coolant may be circulated through the base at a constant flow rate, or at a variable flow rate.

The heater is attached to the heat sink via the thermal interface. The thermal interface allows the heater to be attached to the heat sink even if the mating surfaces between the two are not perfectly flat. The thermal interface may be made of, for example, a thermally conductive epoxy. A thickness of the thermal interface between the heater and the heat sink may be, for example, in a range of 50 μm to 250 μm, and preferably 50 μm to 80 μm.

In the embodiment of FIG. 1, a channel extends through the heat sink, the thermal interface, and the heater, to allow fluidic TIM to flow from the fluidic TIM dispenser to the electronic device contact face of the heater. The channel receives fluidic TIM from the fluidic TIM dispenser. The thermal head may include more than one channel. For example, the thermal head may receive the fluidic TIM from the fluidic TIM dispenser in a single channel via a single tube, and that single channel may branch off in the thermal head into a plurality of channels that each allows the fluidic TIM to be dispensed into the interface between the electronic device contact face of the heater and the electronic device during testing. Alternatively, the heater or portions thereof may be made of a porous material, the fluidic TIM may flow from the fluidic TIM dispenser to the electronic device contact face via the pores of the porous material. The porous material may be, for example, a porous α-Al₂O₃ material, a porous ZrO₂ material, or a porous TiO₂ material. An open porosity of the material may be, for example, between 20% and 50%, and preferably between 28% and 43%. A mean pore size of the material may be, for example, between 1 and 6 μm, and preferably between 1.8 and 5 μm. As another alternative, the TIM may be dispensed via channels or grooves in a surface of the heater (e.g., in a device contact face of the heater).

### Heater Temperature Controller

The heater temperature controller is configured to control a temperature of the heater. An example of a heater temperature controller that may be used in the present systems is described in U.S. Pat. No. 5,864,176. In one embodiment, the heater temperature controller includes a power regulator and a variable power supply. The power regulator receives a temperature signal (for example, via one or more feedback lines from one or more sensors in the thermal head and/or the electronic device) that indicates the present temperature of the electronic device during testing, and receives a set point signal that indicates a desired set point temperature of the electronic device during testing. Based on these two temperatures and/or their rate of change, the power regulator (not shown) generates a control signal indicating the amount of power that should be sent to the heater (for example, via a control line) in order to hold the temperature of the electronic device at the set point temperature. The variable power supply receives the control signal from the power regulator, and sends a portion of the power available from a supply voltage to the heater based on the control signal.

### Fluidic TIM Dispenser and Fluidic TIM Dispenser Controller

The system of FIG. 1 further includes a fluidic TIM dispenser configured to dispense a fluidic TIM between a face of the electronic device and the face of the thermal head, and a fluidic TIM dispenser controller configured to control the TIM dispenser such that the TIM dispenser dispenses the fluidic TIM during testing of the electronic device. In one embodiment, the fluidic TIM dispenser is a fluid pump configured to provide the fluidic TIM to the channel in the thermal head. For example, the TIM dispenser may be a peristaltic pump, a pulse width modulation (PWM) valve pump, or an analog valve pump. The fluidic thermal interface material may be, for example, helium, water, a mixture of water and antifreeze, a thermally conductive di-electric, a thermal coolant, or a phase change material. While the channel for dispensing TIM and the dispense hole are shown to be in a center of the thermal head in the figures, they may be located at other locations in the thermal head.

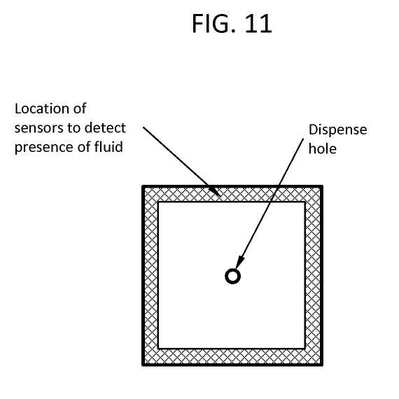

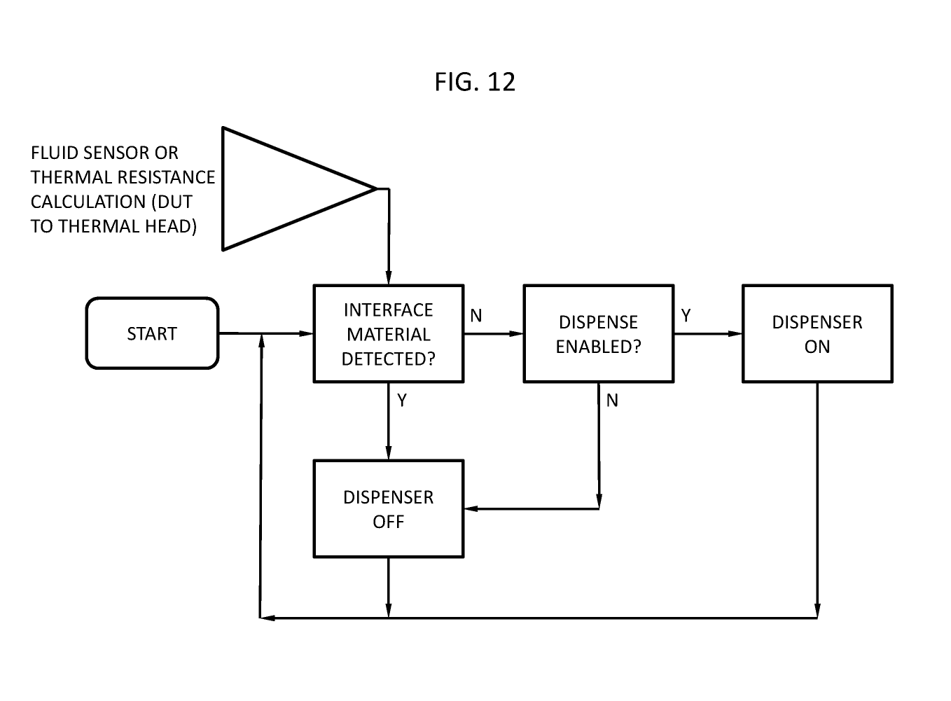

The fluidic TIM dispenser controller may control the TIM dispenser using a timer. The fluidic TIM dispenser controller may control the TIM dispenser such that the TIM dispenser dispenses the fluidic TIM at a predetermined constant rate, or may control the TIM dispenser such that the TIM dispenser dispenses the fluidic TIM at a rate that increases or decreases during testing. The fluidic TIM dispenser controller may control the TIM dispenser to dispense the fluidic TIM based on a signal received from a fluid sensor, as discussed in more detail below with respect to FIGS. 11 and 12.

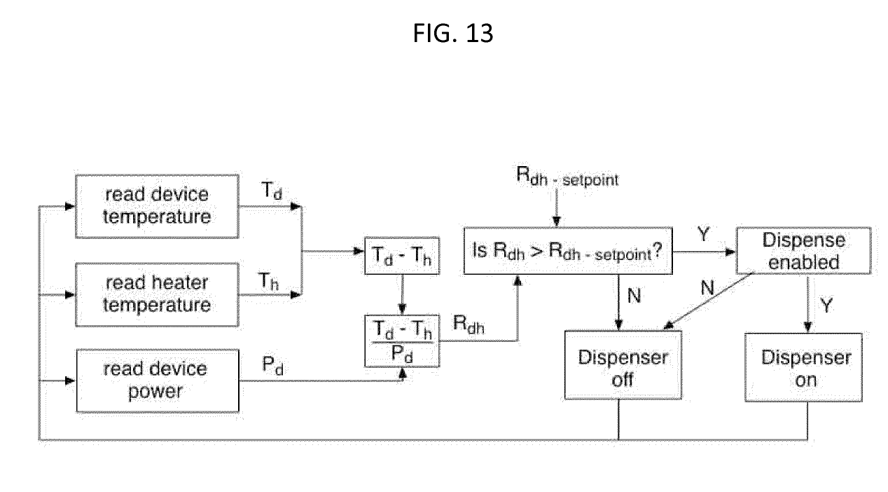

The fluidic TIM dispenser controller may control the TIM dispenser to dispense the fluidic TIM based on a calculation of a thermal resistance, electrical resistance, or electrical capacitance between the electronic device and the thermal head. In other embodiments, the TIM dispenser controller controls the TIM dispenser based on an algorithm that takes into account the type of electronic device, the temperature of the electronic device, temperature of the heater, and/or the power of the electronic device. FIG. 13 is a flow chart showing control of a TIM dispenser in which control of the TIM dispenser is based on. First, the temperature of the electronic device T_{d}, temperature of the heater Tₕ, and power of the electronic device are measured P_{d}. Next, the thermal resistance

$${R}_{dh} = \frac{{T}_{d} - {T}_{h}}{{P}_{d}}$$

is calculated. If the calculated thermal resistance is greater than a predetermined setpoint thermal resistance Rdₕ₋ₛₑₜₚₒᵢₙₜ, and the TIM dispenser is enabled, then the TIM is dispensed. If the TIM dispenser is not enabled, then the TIM is not dispensed, even if the calculated thermal resistance is greater than a predetermined setpoint thermal resistance Rdₕ₋ₛₑₜₚₒᵢₙₜ.

In other embodiments, the TIM can be dispensed via a fluid valve that is controlled by the TIM dispenser controller.

The fluidic thermal interface material may be removed by raising a temperature of the face of the thermal head to a set point above the boiling point of the fluidic thermal interface material. In this manner, manual removal of any residue left by the fluidic thermal interface material is not necessary.

### Second Embodiment

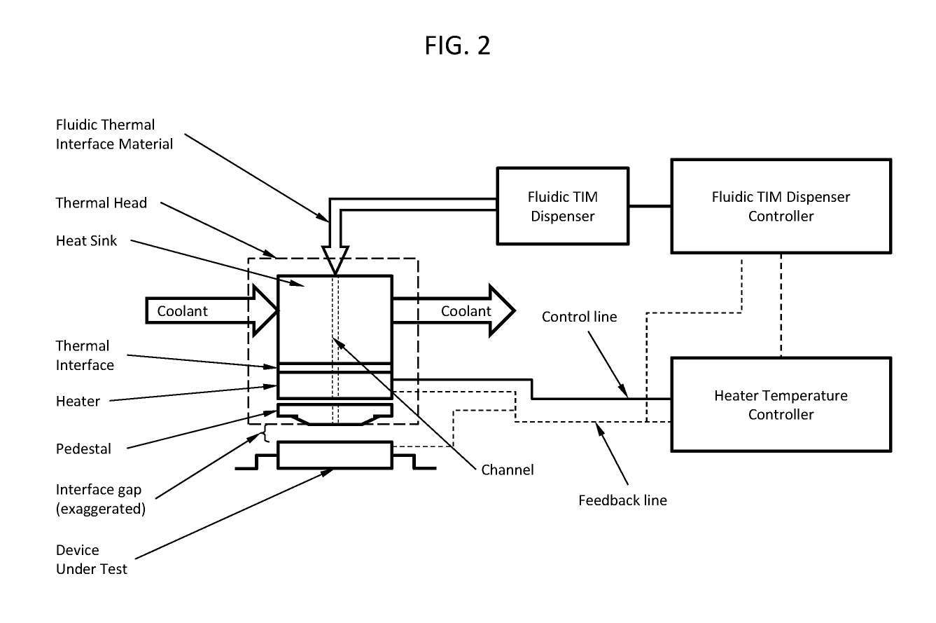

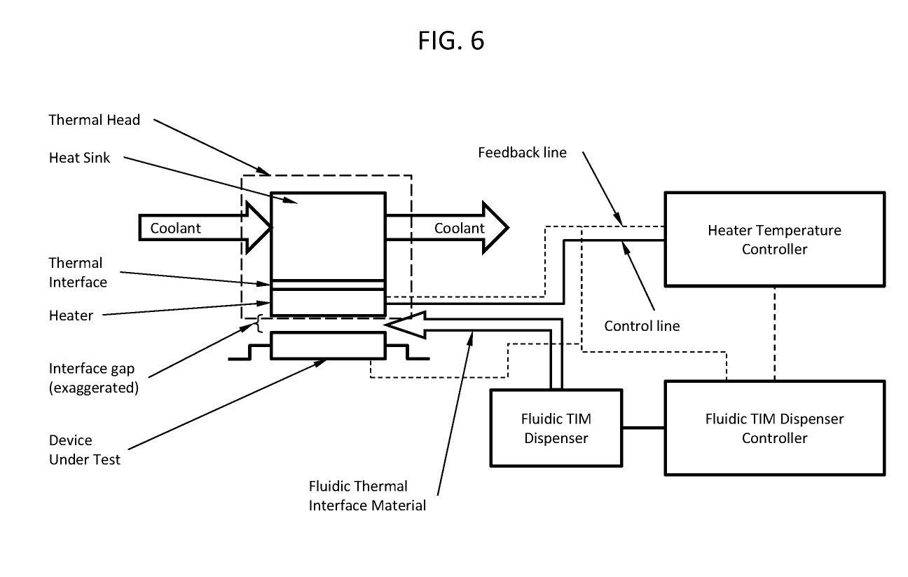

In a second embodiment, depicted in FIG. 2, the heater of the thermal head includes a pedestal that includes the device contact face that is configured to contact the electronic device during testing. The pedestal of the heater is located opposite the heat sink. An example of a pedestal that can be used (or modified for use) in the present systems is described in U.S. Pat. No. 7,639,029. In some embodiments, no modification is necessary, because the fluidic TIM is supplied through side injection (as discussed below with respect to FIG. 6). In other embodiments, the retainer described in U.S. Pat. No. 7,639,029 may be modified by forming a channel or channels extending through the pedestal, so as to be configured to supply the fluidic TIM to a location between a face of the electronic device and the face of the thermal head during testing via the channel or channels.

In the second embodiment, the channel or channels extend through the heat sink, the thermal interface, and the heater (including the pedestal). In FIG. 2, the channel extends vertically through these components of the thermal head, but the invention is not limited to such a vertical configuration of the channel or channels.

The second embodiment is otherwise similar to the first embodiment, discussed above.

### Third Embodiment

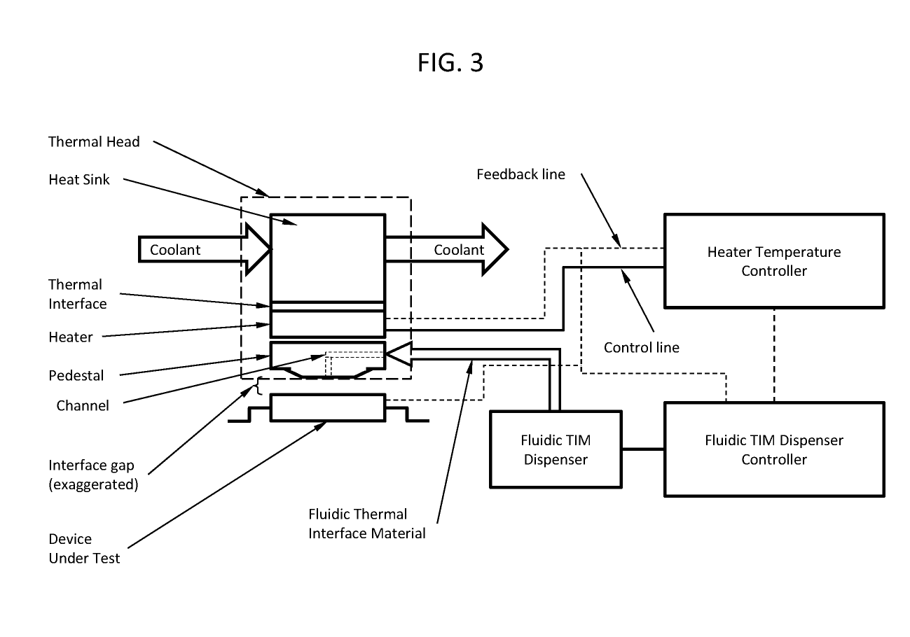

In a third embodiment, shown in FIG. 3, the channel extends only through the heater's pedestal. In FIG. 2, the channel includes a horizontally extending portion, a bent portion, and a vertically extending portion. The fluidic TIM first enters and flows through the horizontally extending portion of the channel, turns at the bend portion, and then flows through the vertically extending portion and out to the device contact face of the pedestal.

The third embodiment is otherwise similar to the second embodiment, discussed above.

### Fourth Embodiment

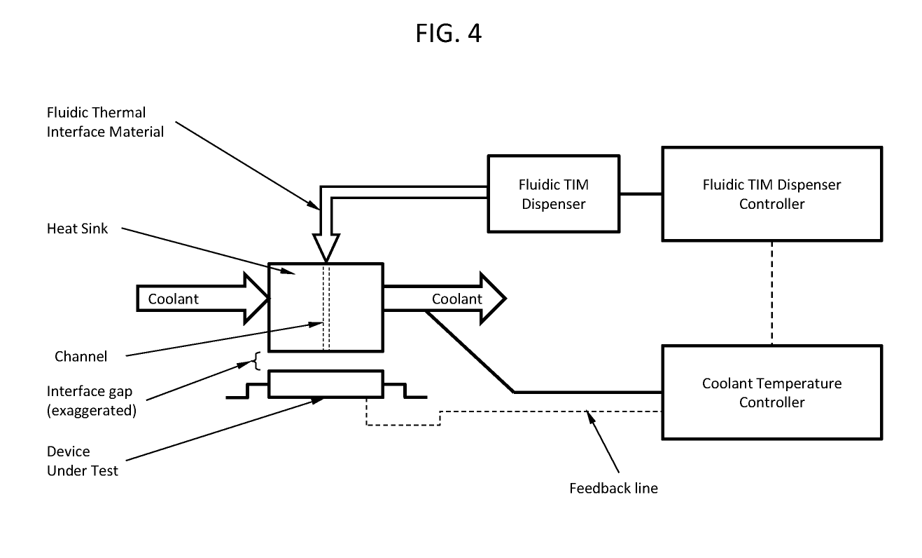

In a fourth embodiment, shown in FIG. 4, the thermal head includes only the heat sink. In some situations, passive control is sufficient to keep an electronic device at the target temperature. For example, if a heat sink is kept at a constant temperature, the thermal resistance provided by the TIM is low enough, and the power is low enough, variation in device temperature can be kept within an acceptable range using only the heat sink. In such a system the temperature of the heat sink may be kept constant during testing. This embodiment may also be used, for example, when electronic devices have been subjected to a heat soak before testing, and therefore do not need to be subjected to external heating by the thermal head before and during testing.

### Fifth Embodiment

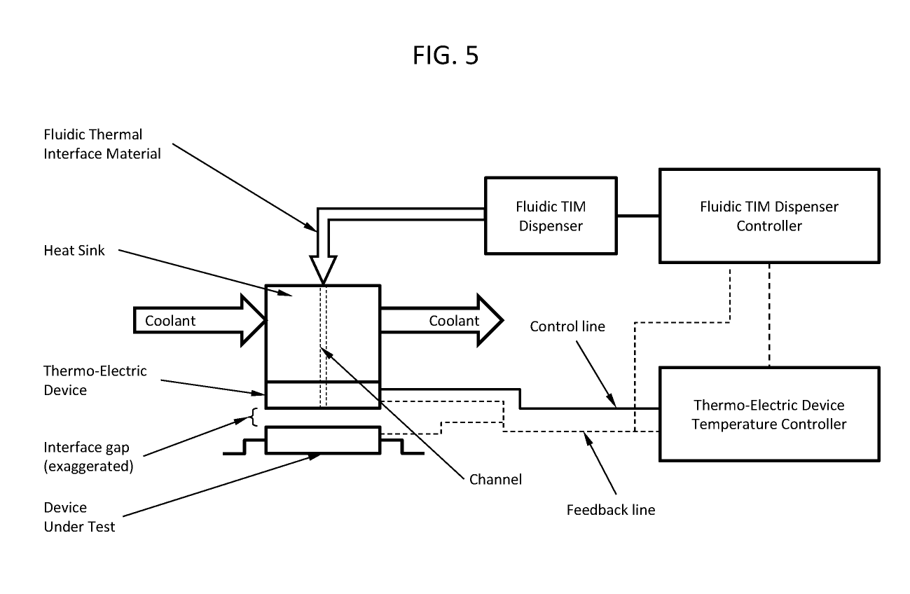

In a fifth embodiment, shown in FIG. 5, the heater of the first embodiment is replaced by a thermo-electric device or a thermal control chip that contains multiple thermoelectric devices. For example, the solid state thermal control device described in U.S. Pat. Nos. 6,825,681 and 6,985,000 may be used (or modified for use) in the present systems. A thermo-electric device is capable of rapid heating and cooling, and may be better suited for maintaining an electronic device at a set point temperature during testing. For example, a thermal control chip may include a plurality of independent solid state thermal elements, which can compensate for inhomogeneity of the power dissipation of the electronic device. In some embodiments, no modification of the devices of U.S. Pat. Nos. 6,825,681 and 6,985,000 is necessary, because the fluidic TIM is supplied through side injection (as discussed below with respect to FIG. 6). In other embodiments, the devices disclosed in these patents are modified such that the channel or channel for supplying fluidic TIM extends through the thermo-electric device or thermal control chip in the same manner as described with respect to the heater in the first embodiment.

### Sixth Embodiment

In a sixth embodiment, shown in FIG. 6, the fluidic TIM dispenser is configured to dispense a fluidic TIM between a face of the electronic device and the face of the thermal head through side injection, thereby eliminating the need for a channel running through the thermal head.

### Other Embodiments

### Interface Gap

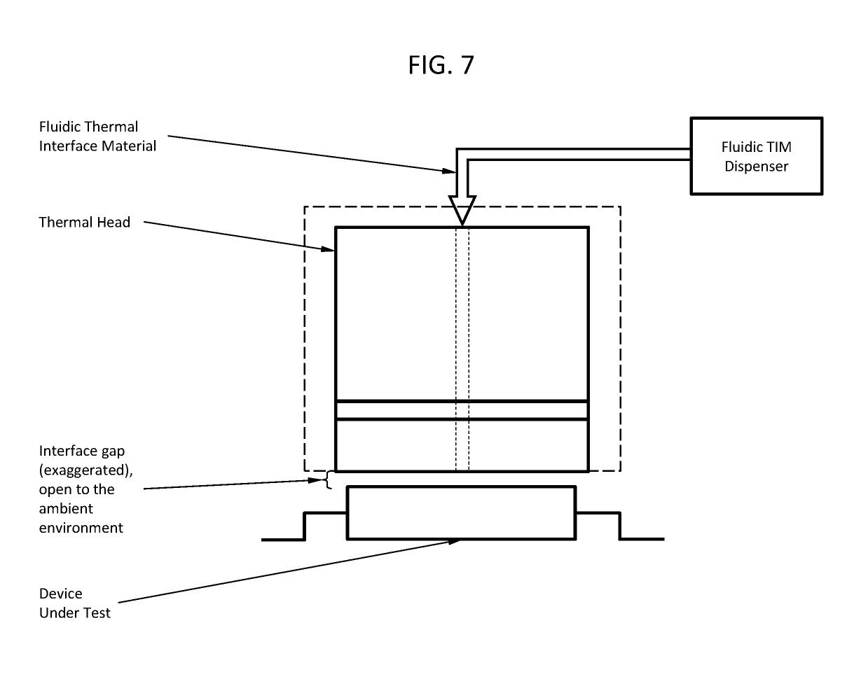

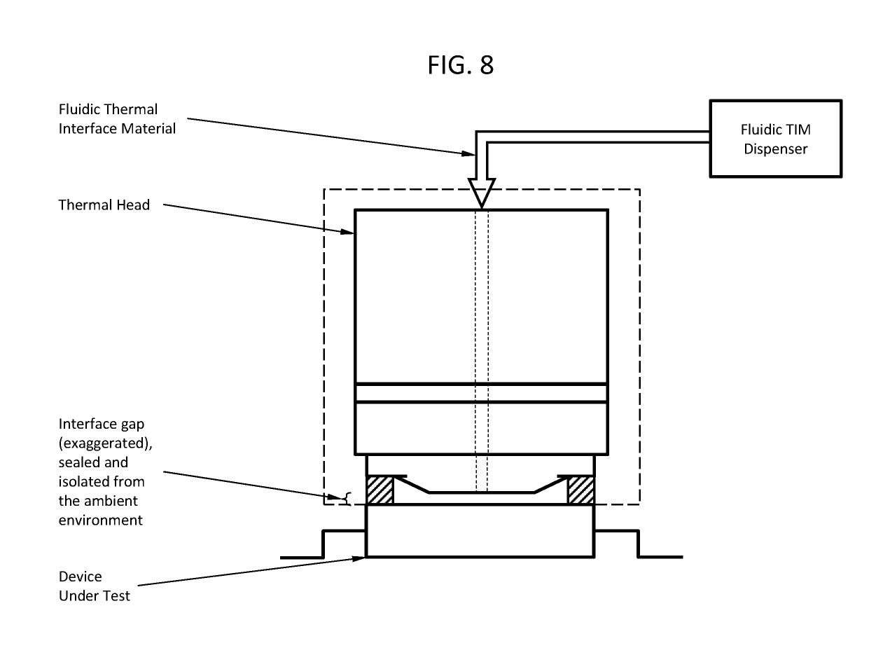

In any of the described amendments, the interface gap between the thermal head and the electronic device may be open to an ambient environment, as shown in FIG. 7, or have a barrier and/or be sealed and isolated from the ambient environment, as shown in FIG. 8.

In the embodiment of FIG. 8, a barrier and/or seal is disposed between the thermal head and the electronic device so as to enclose a central portion of the space. The barrier/seal inhibits the TIM from leaving central portion of the space between the thermal head and the electronic device, so as to prevent the TIM from causing damage to the system and/or the electronic device. The seal and/or the thermal head (e.g., the pedestal of the heater) can have orifices with an orifice size that does not allow liquid TIM (e.g., liquid water) to pass through the seal, but does allow gaseous TIM (e.g., steam) to pass through the seal. The seal may be made of, for example, silicone rubber.

### Thermal Heads Having Hydrophilic and Hydrophobic Coatings

In any of the described embodiments, a hydrophilic or hydrophobic surface/coating may be disposed on portions of the device contact face of the thermal head.

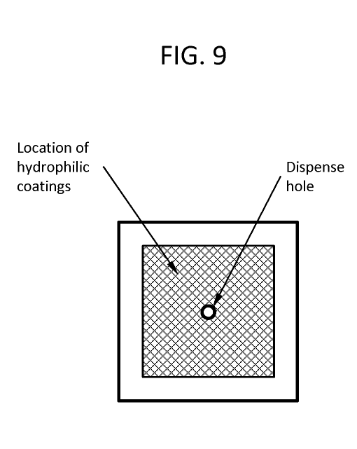

In the embodiment shown in FIG. 9, the hydrophilic coating/surface is located so as to promote wetting at portions of the face/electronic device at which decreased thermal resistance is desired. Specifically, the hydrophilic coating is disposed on the portion of the device contact face that should be contacted by the fluidic TIM during testing. The hydrophilic coating may be, for example, a hydrophilic fumed silica, such as Aerosil® 90, Aerosil® 130, Aerosil® 150, Aerosil® 200, Aerosil® 255, Aerosil® 300, Aerosil® 380, Aerosil® OX 50, Aerosil® TT 600, Aerosil® 200 F, Aerosil® 380F, Aerosil® 200 Pharma, Aerosil® 300 Pharma, available from Evonic Industries; or a micro/nano scale coating such as HydroPhil, available from Lotus Leaf Coatings. While the hydrophilic coating is shown to be in a center of the device contact face in FIG. 9, the hydrophilic coating may be disposed wherever it is desired to promote contact with the TIM.

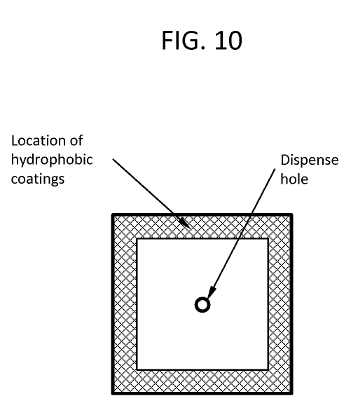

In the embodiment shown in FIG. 10, the hydrophobic coating/surface is located so as to repel fluid from portions of the face/electronic device at which the fluid may cause damage. For example, the hydrophobic coating may be located at a periphery of the device contact surface of the thermal head, so as to inhibit fluid from exiting the interface between the thermal head and the electronic device. The hydrophobic surface may be formed, for example, as described in A. Y. Vorobyev and Chunlei Guo, “Multifunctional surfaces produced by femtosecond laser pulses,” 117 J. App. Phys. 033103 (Jan. 20, 2015). The hydrophobic coating may alternatively be a silicone based liquid-repellant, such as, for example, Rust-oleum® NeverWet; a phosphorus acid based coating, such as those described in U.S. Pat. No. 8,178,004; or a sub-micron scale coating such as HydroFoe, available from Lotus Leaf Coatings. While the hydrophobic coating is shown to be at a periphery of the device contact face in FIG. 10, the hydrophobic coating may be disposed wherever it is desired to inhibit contact with the TIM.

### TIM Dispenser Control

In any of the described embodiments, a fluid sensor may be disposed on portions of the device contact face of the thermal head. The fluid sensor may include, for example, parallel conductors which may be metallized, on the heater or its pedestal that short circuit when they come into contact with the fluidic TIM. In the embodiment shown in FIG. 11, a fluid sensor is disposed around the portion of the device contact face that should be contacted by the fluidic TIM during testing. The fluid sensor is configured to generate a signal indicating whether the fluidic TIM has made contact with the fluid sensor. As shown in FIG. 12, the signal is output from the fluid sensor to the fluidic TIM controller, and the controller is configured to control the fluidic TIM dispenser based on the signal. The TIM dispenser controller turns off the TIM dispenser when the TIM contacts the fluid sensor. The TIM dispenser controller turns on the TIM dispenser if the TIM does not contact the fluid sensor and the TIM dispenser is enabled.

Alternatively, the TIM dispenser controller may control the TIM dispenser based on a thermal resistance, electrical resistance, or electrical capacitance between the electronic device and the thermal head, in a manner similar to that shown in FIG. 13. For example, the power and temperature of the electronic device and the heater temperature can be sensed, so that the thermal resistance between the electronic device and the heater can be calculated. A first temperature sensor or a first plurality of temperature sensors may be used to sense the temperature of the electronic device. A second temperature sensor or a second plurality of temperature sensors may be used to sense the temperature of the heater. If the thermal resistance is higher than a predetermined threshold value, additional TIM can be dispensed. Some test configurations do not allow for measuring device temperature during active testing. Rather, the temperature of the device can only be in between the subtests of a testing cycle. In such a case the dispense of the TIM may only be done in between these subtests of the test cycle.

The foregoing description of embodiments has been presented for purposes of illustration and description. The foregoing description is not intended to be exhaustive or to limit embodiments of the present invention to the precise form disclosed, and modifications and variations are possible in light of the above teachings or may be acquired from practice of various embodiments. The embodiments discussed herein were chosen and described in order to explain the principles and the nature of various embodiments and its practical application to enable one skilled in the art to utilize the present invention in various embodiments and with various modifications as are suited to the particular use contemplated. The features of the embodiments described herein may be combined in all possible combinations of methods, apparatus, modules, systems, and computer program products.

1. A temperature control system for controlling a temperature of an electronic device during testing of the electronic device, the system comprising:
a thermal head having a device contact face configured to contact the electronic device during testing;
a fluidic thermal interface material (TIM) dispenser configured to dispense a fluidic TIM to a location between a face of the electronic device and the device contact face of the thermal head; and
a fluidic TIM dispenser controller configured to control the TIM dispenser such that the TIM dispenser dispenses the fluidic TIM during a test cycle of the electronic device.

2. The temperature control system of claim 1, wherein the thermal head comprises a heater that has the device contact face that is configured to contact the electronic device during testing.

3. The temperature control system of claim 2, wherein the thermal head further comprises a heat sink to which the heater is attached.

4. The temperature control system of claim 3, wherein the heater is attached to the heat sink via a thermally conductive interface material.

5. The temperature control system of claim 2, wherein the fluidic TIM dispenser is configured to dispense the fluidic TIM to the location between the face of the electronic device and the device contact face of the thermal head via at least one channel that extends through the heater.

6. The temperature control system of claim 5, wherein the at least one channel comprises a plurality of channels.

7. The temperature control system of claim 2, wherein at least a portion of the heater is made of a porous material, and the TIM dispenser is configured to dispense the fluidic TIM to the location between the face of the electronic device and the device contact face of the thermal head via pores of the porous material.

8. The temperature control system of claim 3, wherein the TIM dispenser is configured to dispense the fluidic TIM to the location between the face of the electronic device and the device contact face of the thermal head via at least one channel that extends through the heat sink and the heater.

9. The temperature control system of claim 2, wherein the TIM dispenser is configured to dispense the fluidic TIM to the location between the face of the electronic device and the device contact face of the thermal head via a peripheral side of an interface gap between the face of the electronic device and the device contact face of the thermal head.

10. The temperature control system of claim 2, further comprising a heater temperature controller configured to control the heater such that a temperature of the electronic device is maintained at or near a set point temperature.

11. The temperature control system of claim 1, wherein the TIM dispenser is a peristaltic pump, a pulse width modulation valve pump, an analog valve pump, or a fluid valve.

12. The temperature control system of claim 1, wherein the TIM is helium, water, a mixture of water and antifreeze, a thermally conductive di-electric material, a thermal coolant, or a phase change material.

13. The temperature control system of claim 1, wherein the TIM dispenser controller controls the TIM dispenser using a timer.

14. The temperature control system of claim 1, wherein the TIM dispenser controller controls the TIM dispenser such that the TIM dispenser dispenses the fluidic TIM at a predetermined constant rate.

15. The temperature control system of claim 1, wherein the TIM dispenser controller controls the TIM dispenser to dispense the fluidic TIM based on a signal received from a fluid sensor.

16. The temperature control system of claim 1, wherein the TIM dispenser controller controls the TIM dispenser to dispense the fluidic TIM based on a thermal, electrical, or mechanical property of at least one of the thermal head and the electronic device.

17. The temperature control system of claim 1, wherein the TIM dispenser controller controls the TIM dispenser to dispense the fluidic TIM based on a calculation of a thermal resistance, electrical resistance, or electrical capacitance between the electronic device and the thermal head.

18. The temperature control system of claim 17, further comprising one or more first temperature sensors configured to detect a temperature of the electronic device, and one or more second temperature sensors configured to detect a temperature of the thermal head.

19. The temperature control system of claim 1, wherein the thermal head comprises a heater that includes a pedestal that has the device contact face that is configured to contact the electronic device during testing.

20. The temperature control system of claim 19, wherein the thermal head further comprises a heat sink to which the heater is attached, wherein the TIM dispenser is configured to dispense the fluidic TIM to the location between the face of the electronic device and the device contact face of the thermal head via at least one channel that extends through the heat sink and the heater, including the pedestal of the heater.

21. The temperature control system of claim 19, wherein the TIM dispenser is configured to dispense the fluidic TIM to the location between the face of the electronic device and the device contact face of the thermal head via at least one channel that extends through the pedestal of the heater, the TIM entering the pedestal at a side face of the pedestal, and exiting the pedestal at the device contact face of the pedestal.

22. The temperature control system of claim 1, wherein the thermal head comprises a heat sink that has the device contact face that is configured to contact the electronic device during testing.

23. The temperature control system of claim 1, wherein the thermal head comprises a thermo-electric device that has the device contact face that is configured to contact the electronic device during testing.

24. The temperature control system of claim 1, wherein the thermal head comprises a thermal control chip that has the device contact face that is configured to contact the electronic device during testing, the thermal control chip comprising a plurality of independent solid state thermal elements.

25. The temperature control system of claim 1, further comprising a seal attached to the thermal head such that the seal peripherally encloses a central portion of an interface gap between the face of the electronic device and the device contact face of the thermal head.

26. The temperature control system of claim 1, wherein a hydrophilic coating is disposed on a central portion of the device contact face of the thermal head.

27. The temperature control system of claim 1, wherein a hydrophobic coating is disposed on a portion of the device contact face of the thermal head that peripherally surrounds a central portion of the device contact face of the thermal head.

28. The temperature control system of claim 1, wherein a fluid sensor is disposed on a portion of the device contact face of the thermal head that peripherally surrounds a central portion of the device contact face of the thermal head.

29. The temperature control system of claim 28, wherein the TIM dispenser controller controls the TIM dispenser to dispense the fluidic TIM based on a signal received from the fluid sensor.

30. The temperature control system of claim 1, wherein the TIM is dispensed via a plurality of grooves in the device contact face of the thermal head.

31. A method of controlling a temperature of an electronic device during testing of the electronic device, the method comprising:
contacting a device contact face of a thermal head against an electronic device and testing the electronic device; and
while contacting the device contact face of the thermal head against the electronic device and performing a test cycle, dispensing a fluidic thermal interface material to a location between a face of the electronic device and the device contact face of thermal head.

32. The method of claim 31, further comprising raising a temperature of the contact face of the thermal head to a set point above the boiling point of the fluidic thermal interface material.
